(19) United States
(12) Patent Application Publication
(10) Pub. No.: US 2025/0006738 A1
(43) Pub. Date: Jan. 2, 2025

(54) STACKED TRANSISTOR STRUCTURES WITH DIFFERENT RIBBON MATERIALS

(71) Applicant: Intel Corporation, Santa Clara, CA (US)

(72) Inventors: Nicole K. THOMAS, Portland, OR (US); Iulian HETEL, Brussels (BE); Marko RADOSAVLJEVIC, Portland, OR (US)

(21) Appl. No.: 18/345,168

(22) Filed: Jun. 30, 2023

(51) Int. Cl. H01L 27/092; H01L 21/822; H01L 21/8238; H01L 29/06; H01L 29/423; H01L 29/66; H01L 29/775

(52) U.S. Cl. CPC H01L 27/0922; H01L 21/8221; H01L 21/823807; H01L 29/0673; H01L 29/42392; H01L 29/66439; H01L 29/775

(57) ABSTRACT

Embodiments described herein may be related to apparatuses, processes, systems, and/or techniques for integrating different materials into the channels for stacked transistor devices, for example in a CFET configuration, where the bottom device is an NMOS device and the top device is a PMOS device, or vice versa. Other embodiments may be described and/or claimed.

### FIELD

Embodiments of the present disclosure generally relate to the field of semiconductor manufacturing, and in particular to fabricating stacked transistor structures.

### BACKGROUND

Continued growth in virtual machines, cloud computing, and portable devices will continue to increase the demand for high density transistors within chips and packages. In addition, there will be an increased need for producing stacked transistor structures that have alternate doping profiles, for example an NMOS transistor structure on a PMOS transistor structure or vice versa.

### BRIEF DESCRIPTION OF THE DRAWINGS

FIG. 1 shows a perspective view of three layers of transistor structures stacked on each other, where the layers are alternate NMOS and PMOS layers, in accordance with various embodiments.

FIGS. 2A-2H show cross section gate cut views of stages in a manufacturing process for a device that includes two transistor structure layers stacked on each other, with one layer NMOS and the other layer PMOS, where ribbons are regrown from the epitaxial structures, in accordance with various embodiments.

FIGS. 3A-3F show cross section gate cut views of stages in a manufacturing process for a device that includes two transistor structure layers stacked on each other, with one layer NMOS and the other layer PMOS, where ribbons are regrown from silicon adjacent to the epitaxial structures, in accordance with various embodiments.

FIG. 4 illustrates an example process for manufacturing a device that includes two transistor structure layers stacked on each other, with one layer at a first doping level and the other layer at a second doping level, in accordance with various embodiments.

FIG. 5 illustrates a computing device in accordance with one implementation of the invention.

FIG. 6 illustrates an interposer that includes one or more embodiments of the invention.

### DETAILED DESCRIPTION

Embodiments described herein may be related to apparatuses, processes, systems, and/or techniques for integrating different materials into stacked transistor structures, where the bottom transistor structure, which may be referred to as the bottom device, and the top transistor structure, which may be referred to as the top device, may be different devices, e.g. one NMOS and one PMOS. In embodiments, the stacked transistor structure is in a complimentary field-effect transformer (CFET) configuration. In some embodiments, sacrificial ribbons, which may be silicon ribbons or silicon germanium ribbons, may be removed from the top device and replaced with a different epitaxially grown channel material. In embodiments, the source epitaxial structure and the drain epitaxial structure may be used as a template for the channel growth. In embodiments, the channel may be referred to as a ribbon or a nanoribbon.

In some embodiments, the sacrificial ribbons may be partially removed from the top device, with some residual material of the sacrificial ribbons adjacent to the source epitaxial structure and the drain epitaxial structure. The different grown channel material may be grown from the residual material adjacent to the source epitaxial structure and the drain epitaxial structure. In embodiments, this residual material may be silicon. Embodiments described herein may be referred to as a process for channel regrowth from a source or from a drain for stacked transistor architectures, and may use a portion of a sacrificial ribbon for channel regrowth.

These techniques may allow integration of different channel materials, which may be referred to as different ribbon materials, on the same wafer. For example, a silicon channel material for a bottom device and a second different channel material for the top device. In embodiments, the techniques described herein may also be used to create different compositions of gate materials in the top device and the bottom device. In embodiments, these techniques may also be used to create different doped epitaxial materials, serving as a source or drain, in the top device and the bottom device, or within a particular device.

In embodiments, due to growth of channels from each of the epitaxial structures for the top device, there may be irregularities in the shape of these grown channels. In some embodiments, there may be joints where the different crystalline structures meet toward the center of the channels. In embodiments, there may be a difference in the crystallinity of the ribbons and the top device versus the bottom device. In embodiments, this may be referred to as a discontinuous crystalline structure, or a ply-crystalline structure.

Alternative embodiments may include using layer transfer techniques to integrate different channel materials that are grown on a second wafer to create stacked transistor structures. However, these legacy techniques may come with an increased number of defects, lowering overall yield. In addition, these legacy techniques increase cost due to the requirement of a secondary substrate. In addition, these legacy techniques would not allow different top ribbon materials to be manufactured on the same wafer. In addition, options for integrating materials using layer transfer techniques may be limited due to the need for a bonding layer during the layer transfer process.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

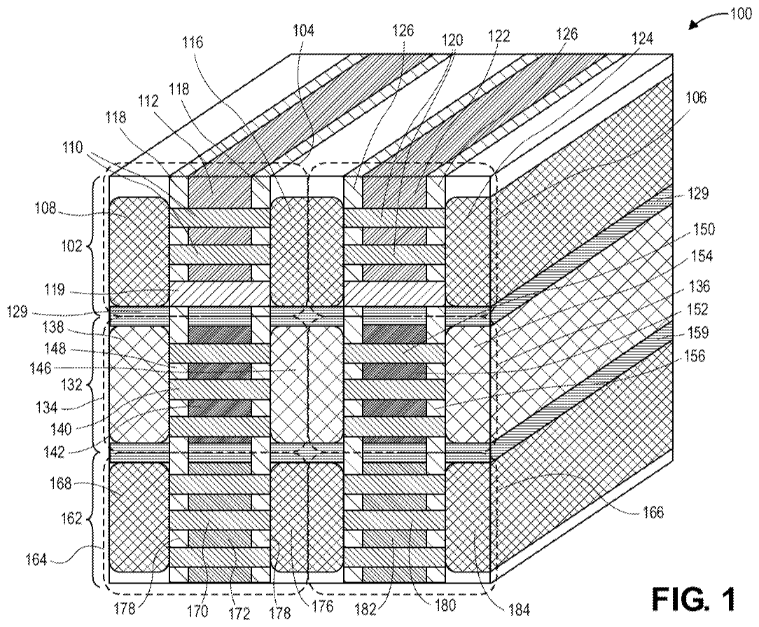

FIG. 1 shows a perspective view of three layers of transistor structures stacked on each other, where the layers have alternate NMOS and PMOS, in accordance with various embodiments. Stacked transistor structure 100 includes three layers 102, 132, 162 that are stacked on each other. In embodiments, the layers 102, 132, 162 may be in a CFET configuration. In embodiments, the layers 102, 132, 162 may be formed on a single wafer (not shown).

Layer 102 may include devices 104, 106, and layer 132 may include devices 134, 136, and layer 162 may include devices 164, 166. In embodiments, the devices 104, 106 of layer 102 may be either in NMOS or PMOS devices, the devices 134, 136 of layer 132 may be either NMOS or PMOS devices, and the devices 164, 166 of layer 162 may be either NMOS or PMOS devices. In embodiments, the identification of a device as either NMOS or PMOS may also be referred to as the devices having different doping levels. In embodiments, the epitaxial sources and/or drains may have different doping levels, and different work function materials may surround the channels. In embodiments, the channels may be different materials, such as silicon or germanium.

In embodiments, in layer 102, device 104 may include epitaxial structures 108, 116, with ribbons 110 that extend between the epitaxial structures 108, 116, and through gate material 112. In embodiments, a gate spacer 118, which may be a dielectric material, may separate the gate material 112 from the epitaxial structures 108, 116. In embodiments, a gate dielectric 119 may be at the bottom of the gate material 112 and between the gate spacer 118. Device 106 may include epitaxial structures 116, 124, with ribbons 120 that extend between the epitaxial structures 116, 124, and through gate material 122. In embodiments, a gate spacer 126 may separate the gate material 122 from epitaxial structures 116, 124. In embodiments, a liner 129, which may be a dielectric, may be below the gate dielectric 119, and may be partially between the gate spacers 118. In embodiments, the liner 129, for example, may electrically isolate the epitaxial structure 116 from the epitaxial structure 146. In embodiments, the ribbons 110, 120 may be doped for NMOS or for PMOS.

In embodiments, in layer 132, device 134 may include epitaxial structures 138, 146, with ribbons 140 that extend between the epitaxial structures 138, 146, and through gate material 142. In embodiments, a gate spacer 148 may separate the gate material 142 from the epitaxial structures 138, 146. In embodiments, a gate dielectric 119 may be at the top of the gate material 142 and separate gate material 142 from gate material 112. In embodiments, the gate dielectric 119 may physically couple with the gate spacer 148. Device 136 may include epitaxial structures 146, 154, with ribbons 150 that extend between the epitaxial structures 146, 154, and through gate material 152. In embodiments, a gate spacer 156 may separate the gate material 152 from epitaxial structures 146, 154. In embodiments, the ribbons 140, 150 may be doped for NMOS or for PMOS, and may have a different doping level than the doping level of ribbons 110, 120.

In embodiments, in layer 162, device 164 may include epitaxial structures 168, 176, with ribbons 170 that extend between the epitaxial structures 168, 176, and through gate material 172. In embodiments, a gate spacer 178 may separate the gate material 172 from the epitaxial structures 168, 176. In embodiments, the gate material 172 may be in contact with the gate material 142 of device 134. In other embodiments, the top and bottom gates may be separated by a layer of dielectric material. Device 166 may include epitaxial structures 176, 184, with ribbons 180 that extend between the epitaxial structures 176, 184, and through gate material 182. In embodiments, the ribbons 140, 150 may be doped for NMOS or for PMOS, and may have a different doping level than the doping level of ribbons 110, 120, or of the ribbons 140, 150. In embodiments, a liner 159, which may be similar to liner 129, may at least partially separate layer 132 from layer 162.

In embodiments, the gate spacers, such as gate spacers 118, 148, 178 may be contiguous structures throughout the layers 102, 132, 162. In embodiments, the gate material 112, 122, 142, 152, 172, 182 may include the same material, such as a metal, or may include different materials. In embodiments, the material of the epitaxial structures 108, 116, 124 may be different than the material of the epitaxial structures 138, 146, 154, depending upon whether the layer is an NMOS layer or a PMOS layer. In embodiments, during fabrication, the epitaxial structures such as epitaxial structures 108, 116, 124 may be removed and different material for these epitaxial structures may be used depending on whether the layer is an NMOS layer or a PMOS layer.

In embodiments, one or more trench contacts (TCN) (not shown) may be fabricated to couple with various parts of the stacked transistor structure 100. Other embodiments may include shared contacts (not shown) between the top and bottom device, and/or isolated contacts between the top and bottom device. In embodiments, contacts may be performed from either the wafer front side (not shown) or the wafer backside (not shown).

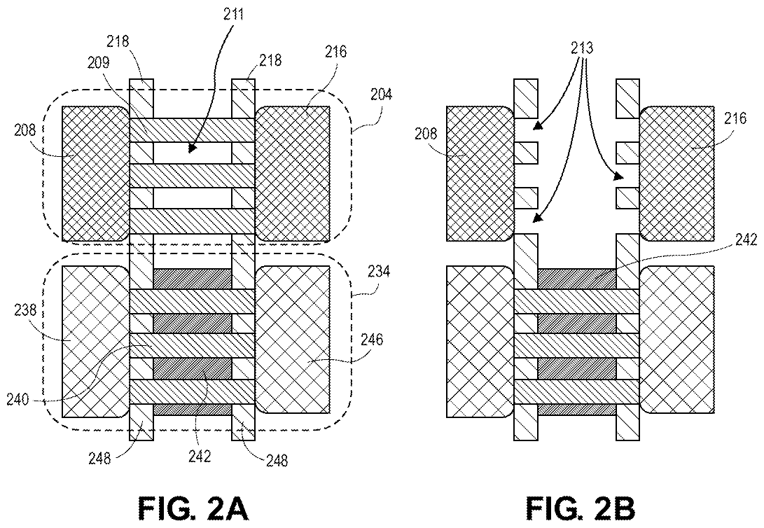

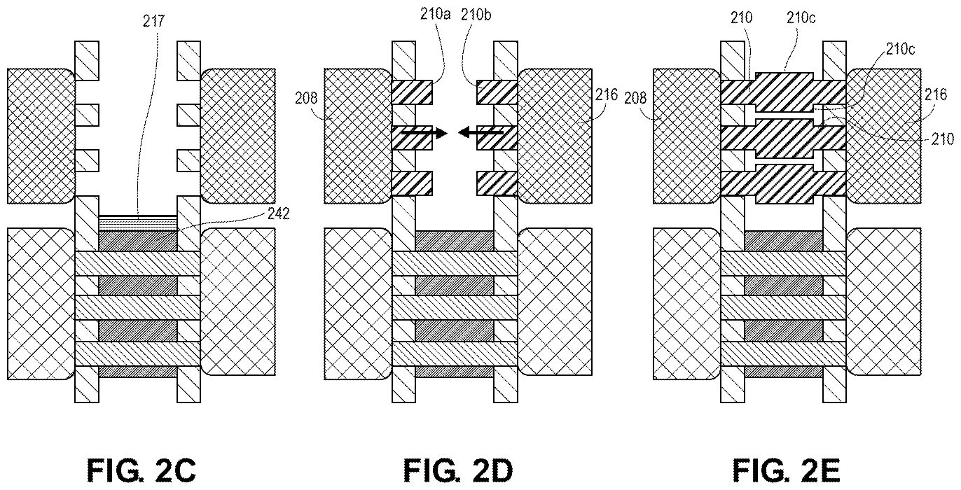

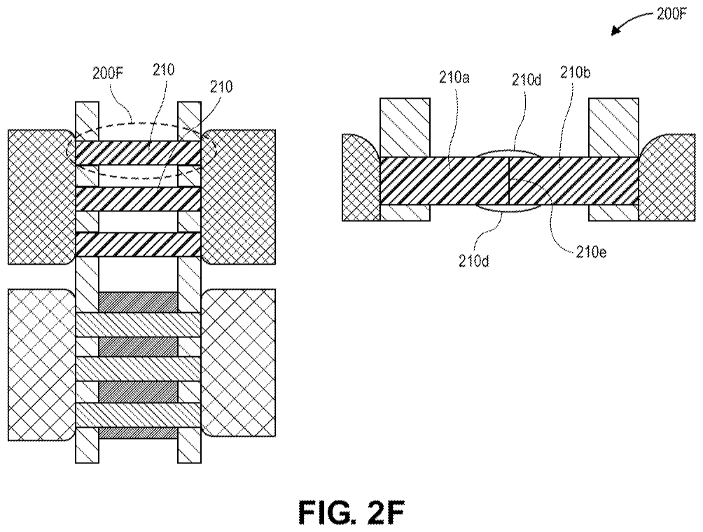

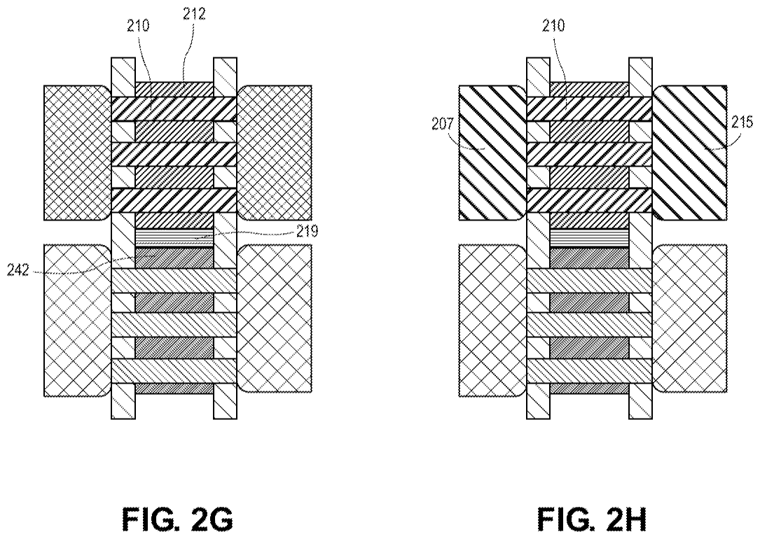

FIGS. 2A-2E show cross section gate cut views of stages in a manufacturing process for a device that includes two transistor structure layers stacked on each other, with one layer NMOS and the other layer PMOS, where ribbons are regrown from the epitaxial structures, in accordance with various embodiments. FIG. 2A shows a cross-section gate cut view of a stage in the manufacturing process that shows a portion of a top device 204 that is on a bottom device 234, where top device 204 may be similar to top device 104 and bottom device 234 may be similar to bottom device 134 of FIG. 1.

At this stage of the manufacturing process, the bottom device 234 may include epitaxial structures 238, 246, which may be similar to epitaxial structures 138, 146 of FIG. 1. In embodiments, the epitaxial structure 238 may be a source and the epitaxial structure 246 may be a drain, or vice versa.

In embodiments, ribbons 240 may extend between the epitaxial structures 238, 246, and may extend through a gate material 242. These may be similar to epitaxial structures 138, 146 and gate material 142 of FIG. 1. In embodiments, a gate spacer 248 may separate the gate material 242 from the epitaxial structures 238, 246. In embodiments, the ribbons 240 may extend through the gate spacer 248 to directly physically couple with the epitaxial structures 238, 246.

In embodiments, the top device 204, which may be similar to top device 104 of FIG. 1, may include epitaxial structures 208, 216, which may be similar to epitaxial structures 108, 116 of FIG. 1. In embodiments, sacrificial ribbons 209 may extend between the epitaxial structures 208, 216, and may be similar to ribbons 240. In embodiments, the ribbons 240 and sacrificial ribbons 209 may be made of silicon, or silicon germanium, depending on whether the bottom device 234 is an NMOS or PMOS device. In embodiments, the sacrificial ribbons 209 may extend through gate spacer 218, which may be similar to gate spacer 118 of FIG. 1, and directly physically couple with the epitaxial structures 208, 216. In embodiments, empty space 211 may be between and surround at least a portion of the sacrificial ribbons 209.

In embodiments, the ribbons 240 for the bottom device 234 and the sacrificial ribbons 209 for the top device 204 may be manufactured on the same wafer (not shown) and may be made of the same material. For example, all silicon, or all silicon/germanium, depending upon the desired doping level (NMOS or PMOS) for the bottom device 234.

FIG. 2B shows a cross-section gate cut view of a stage in the manufacturing process where the sacrificial ribbons 209 of FIG. 2A have been etched away, for example using a wet etch process, or some other omnidirectional etching process, to create cavities 213 that expose portions of the epitaxial structures 208, 216. In embodiments, the wet etch process, or other omnidirectional etching process may be selective to the sacrificial ribbons 209, and to the epitaxial structures 208, 216. Note that the gate material 242 may serve as a stop for the etch process, such that the ribbons 240 are not affected. In some embodiments, the gate material 242 may be a protective fill, that may be subsequently removed (not shown) and filled with a gate material.

FIG. 2C shows a cross-section gate cut view of an alternate stage in the manufacturing process described with respect to FIG. 2B, where a protective material 217 may be placed above the gate material 242 prior to the wet etch process, or other omnidirectional etching process. In embodiments, the protective material 217 may include an oxide, silicon, and/or carbon. In embodiments, the protective material 217 may be deposited using atomic layer deposition (ALD) process.

FIG. 2D shows a cross-section gate cut view of a stage in the manufacturing process, following the stage described in FIG. 2B, where partial ribbons 210a may be grown from the epitaxial structure 208, and where partial ribbons 210b may be grown from the epitaxial structure 216. In embodiments, a seeding process may be used to grow the ribbons 210a, 210b based upon the crystalline structure of the epitaxial structures 208, 216. In embodiments, the growth rate of the partial ribbons 210a, 210b in a horizontal direction may be significantly faster than any growth of the partial ribbons 210a, 210b in the vertical direction

FIG. 2E shows a cross-section gate cut view of a stage in the manufacturing process, where ribbons 210 are formed when the partial ribbons 210a, 210b meet during the growth process. In embodiments, growth of the partial ribbons 210a, 210b of FIG. 2D may result in non-uniformity within the resulting ribbons 210, for example excess material 210c between the ends of the ribbons 210 that may be proximate to the epitaxial structures 208, 216, and as a result may create a thickness toward the middle of the ribbons 210 that is greater than a thickness of the ribbons 210 at their ends.

FIG. 2F shows a cross-section gate cut view of a stage in the manufacturing process, along with a partial expanded diagram 200F, where ribbons 210 may be subjected to a sacrificial oxidation process, or similar process, to shape a side of the ribbons into more of a planar structure. In embodiments, the sacrificial oxidation process may be applied to reduce the deformities 210d within the ribbons 210. In addition, there may be a seam 210e within the partial ribbon 210a and the partial ribbon 210b at the point where they meet after the growth process. In embodiments, this seam 210e may be referred to as a joint, and may be characterized by a mismatching of crystalline structure between the partial ribbon 210a and the partial ribbon 210b.

FIG. 2G shows a cross-section gate cut view of a stage in the manufacturing process where a gate material 212, which may be similar to gate material 112 of FIG. 1, is placed around the ribbons 210. In embodiments, a gate dielectric 219, which may be similar to gate dielectric 119 of FIG. 1, may be placed upon the gate material 242 prior to the gate material 212 being placed.

FIG. 2H shows a cross-section gate cut view of a stage in the manufacturing process where the epitaxial structures 208, 216 of FIG. 2E may be removed and replaced with epitaxial structures 207, 215. In embodiments, the ribbons 210 may be in direct physical contact with the replaced epitaxial structures 207, 215. Note that in some embodiments, if the ribbons 210 material has been change, for example grown as discussed above, the replacement epitaxial structures 207, 215 may be chosen to optimize contact resistance for the ribbons 210.

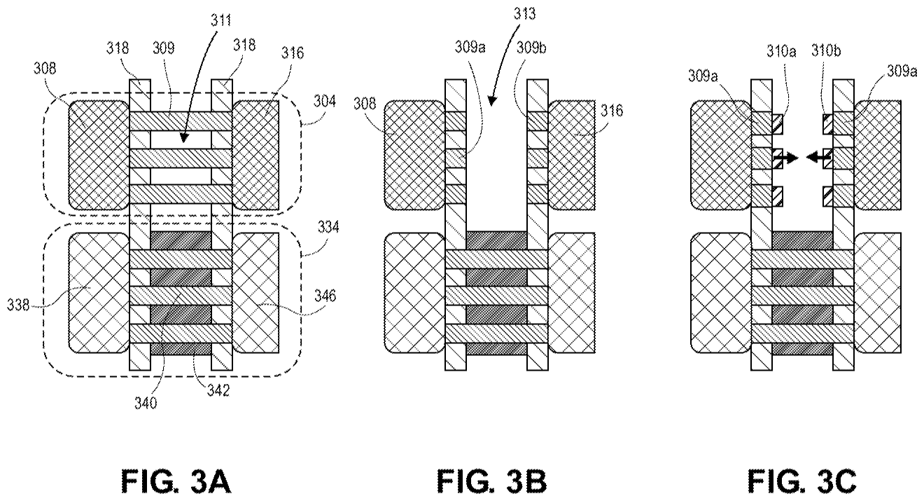

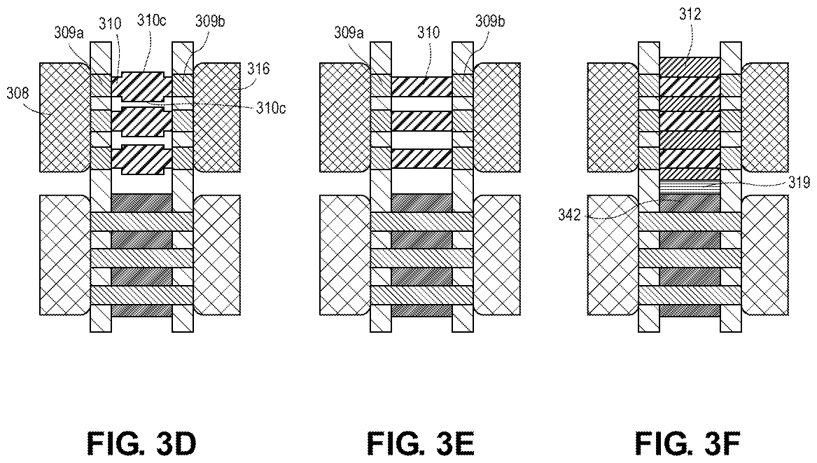

FIGS. 3A-3F show cross section gate cut views of stages in a manufacturing process for a device that includes two transistor structure layers stacked on each other, with one layer NMOS and the other layer PMOS, where ribbons are regrown from silicon adjacent to the epitaxial structures, in accordance with various embodiments. FIG. 3A shows a cross-section gate cut view of a stage in the manufacturing process that shows a portion of a top device 304 that is on a bottom device 334, where top device 304 may be similar to top device 104 and bottom device 334 may be similar to bottom device 134 of FIG. 1.

At this stage of the manufacturing process, the bottom device 334 may include epitaxial structures 338, 346, which may be similar to epitaxial structures 138, 146 of FIG. 1. In embodiments, the epitaxial structure 338 may be a source and the epitaxial structure 346 may be a drain, or vice versa.

In embodiments, ribbons 340 may extend between the epitaxial structures 338, 346, and may extend through a gate material 342. These may be similar to epitaxial structures 138, 146 and gate material 142 of FIG. 1. In embodiments, a gate spacer 318 may separate the gate material 342 from the epitaxial structures 338, 346. In embodiments, the ribbons 340 may extend through the gate spacer 318 to directly physically couple with the epitaxial structures 338, 346.

In embodiments, the top device 304, which may be similar to top device 104 of FIG. 1, may include epitaxial structures 308, 316, which may be similar to epitaxial structures 108, 116 of FIG. 1. In embodiments, sacrificial ribbons 309 may extend between the epitaxial structures 308, 316, and may be similar to ribbons 340. In embodiments, the ribbons 340 and sacrificial ribbons 309 may be made of silicon, or silicon germanium, depending on whether the bottom device 334 is an NMOS or PMOS device. In embodiments, the sacrificial ribbons 309 may extend through gate spacer 318, which may be similar to gate spacer 118 of FIG. 1, and directly physically couple with the epitaxial structures 308, 316. In embodiments, empty space 311 may be between and surround at least a portion of the sacrificial ribbons 309.

In embodiments, the ribbons 340 for the bottom device 334 and the sacrificial ribbons 309 for the top device 304 may be manufactured on the same wafer (not shown) and may be made of the same material. For example, all silicon, or all silicon/germanium, depending upon the desired doping level (NMOS or PMOS) for the bottom device 334.

FIG. 3B shows a cross-section gate cut view of a stage in the manufacturing process where a portion of the sacrificial ribbons 309 of FIG. 3A have been etched away, for example using an anisotropic etch, to create cavity 313 where sacrificial ribbon portions 309a of the sacrificial ribbons 309 remain proximate to the epitaxial structure 308, and where sacrificial ribbon portions 309b of the sacrificial ribbons 309 remain proximate to the epitaxial structure 316.

Note that the gate material 342 may serve as a stop for the etch process, such that the ribbons 340 are not affected by the etch. In some embodiments, the gate material 342 may be a protective fill, that may be subsequently removed (not shown) and filled with a gate material.

FIG. 3C shows a cross-section gate cut view of a stage in the manufacturing process where partial ribbons 310a may be grown from the sacrificial ribbons portion 309a, and where partial ribbons 310b may be grown from the sacrificial ribbons portion 309b. In embodiments, a seeding process may be used to grow the ribbons 310a, 310b based upon the crystalline structure of sacrificial ribbons portions 309a, 309b. In embodiments, the seeding process may include a selective deposition of a catalytic seed on crystalline material within the sacrificial ribbons portions 309a, 309b. In embodiments where the sacrificial ribbon 309 is silicon, no seeding may be needed. In embodiments, the growth rate of the partial ribbons 310a, 310b in a horizontal direction toward each other may be significantly faster than growth of the partial ribbons 310a, 310b in the vertical direction.

FIG. 3D shows a cross-section gate cut view of a stage in the manufacturing process, where ribbons 310 are formed when the partial ribbons 310a, 310b meet during the growth process. In embodiments, growth of the partial ribbons 310a, 310b of FIG. 3C may result in non-uniformity within the resulting ribbons 310, for example, deformities 310c, which may include excess material, between the ends of the ribbons 310 that may be proximate to the epitaxial structures 308, 316, and as a result may create a thickness toward the center of the ribbons 310 that is wider than a thickness of the ribbons 310 at their ends.

FIG. 3E shows a cross-section gate cut view of a stage in the manufacturing process, where ribbons 310 may be subjected to a sacrificial oxidation process, or similar process, to shape a side of the ribbons into more of a planar structure. In embodiments, the sacrificial oxidation process may be applied to reduce the deformities 310c of FIG. 3D within the ribbons 310. In addition, there may be a seam (not shown) within the ribbon 310 where the partial ribbons 310a, 310b meet after the growth process described above with respect to FIG. 3C. This seam (not shown) may be similar to seam 210e of FIG. 2F, and may be characterized by a mismatching of crystalline structure between the partial ribbon 310a and the partial ribbon 310b of FIG. 3C. In some embodiments, there may be a single crystalline structure that meets at this seam (not shown). In some embodiments, there may be a single crystalline structure because growth occurred from just one side.

FIG. 3F shows a cross-section gate cut view of a stage in the manufacturing process where a gate material 312, which may be similar to gate material 112 of FIG. 1, is placed around the ribbons 310. In embodiments, a gate dielectric 319, which may be similar to gate dielectric 119 of FIG. 1, may be placed upon the gate material 342 prior to the gate material 312 being placed.

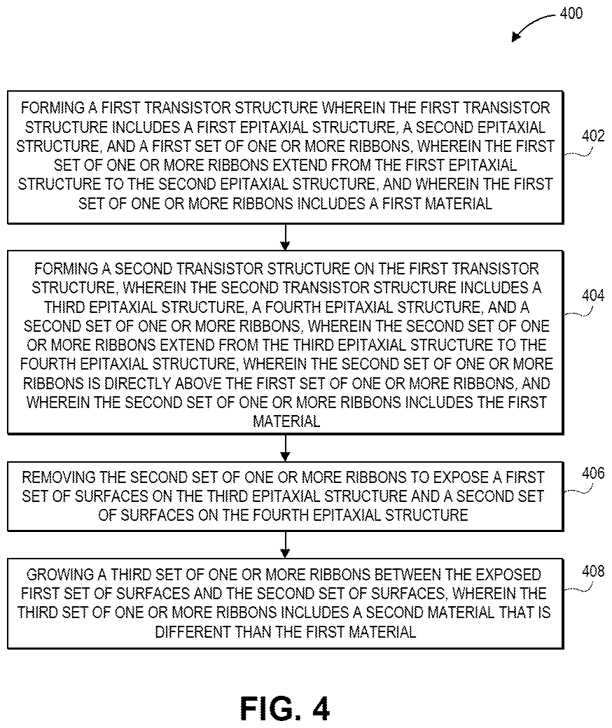

FIG. 4 illustrates an example process for manufacturing a device that includes two transistor structure layers stacked on each other, with one layer at a first doping level and the other layer at a second doping level, in accordance with various embodiments. Process 400 may be performed using the techniques, processes, apparatus, or systems described herein, and in particular with respect to FIGS. 1-3F.

At block 402, the process may include forming a first transistor structure wherein the first transistor structure includes a first epitaxial structure, a second epitaxial structure, and a first set of one or more ribbons, wherein the first set of one or more ribbons extend from the first epitaxial structure to the second epitaxial structure, and wherein the first set of one or more ribbons has a first doping profile.

At block 404, the process may further include forming a second transistor structure on the first transistor structure, wherein the second transistor structure includes a third epitaxial structure, a fourth epitaxial structure, and a second set of one or more ribbons, wherein the second set of one or more ribbons extend from the third epitaxial structure to the fourth epitaxial structure, wherein the second set of one or more ribbons is directly above the first set of one or more ribbons, and wherein the second set of one or more ribbons has the first doping profile.

At block 406, the process may further include removing the second set of one or more ribbons to expose a first set of surfaces on the third epitaxial structure and a second set of surfaces on the fourth epitaxial structure.

At block 408, the process may further include growing a third set of one or more ribbons between the exposed first set of surfaces and the second set of surfaces, wherein the third set of one or more ribbons has a second doping profile that is different from the first doping profile.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And, in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

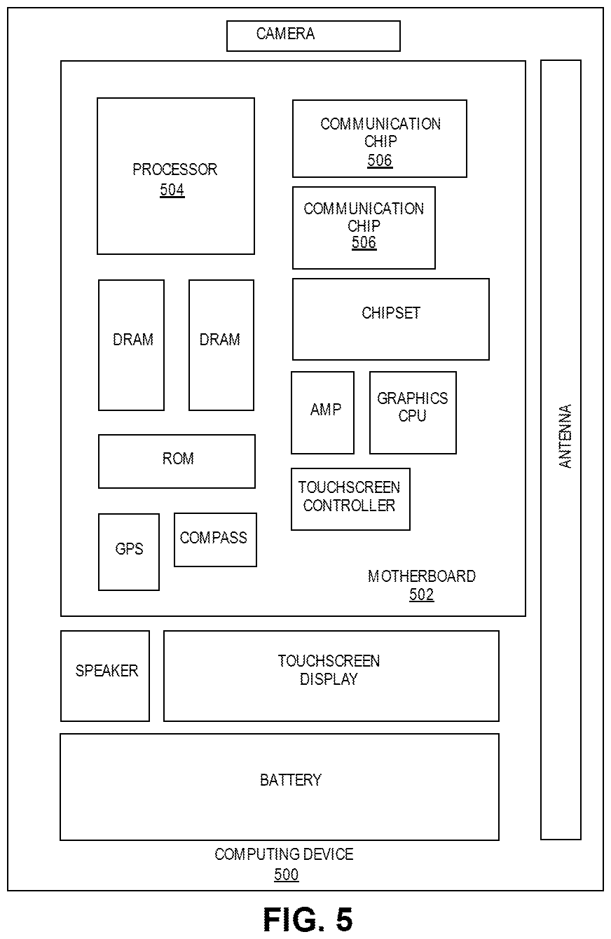

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip includes one or more devices, such as MOS-FET transistors built in accordance with implementations of the invention.

In further implementations, another component housed within the computing device 500 may contain an integrated circuit die that includes one or more devices, such as MOS-FET transistors built in accordance with implementations of the invention.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

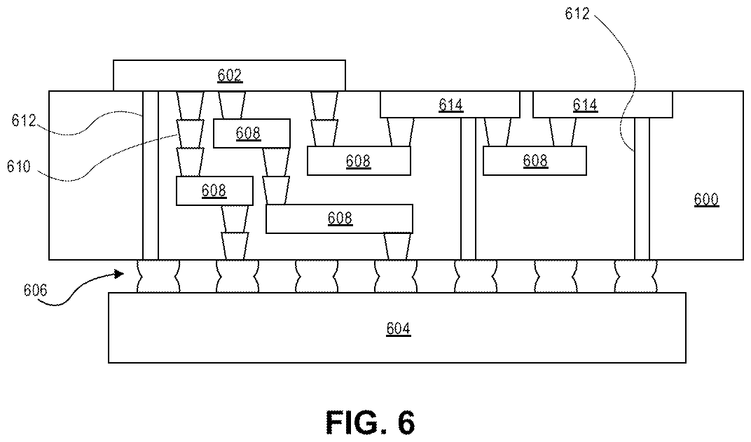

FIG. 6 illustrates an interposer 600 that includes one or more embodiments of the invention. The interposer 600 is an intervening substrate used to bridge a first substrate 602 to a second substrate 604. The first substrate 602 may be, for instance, an integrated circuit die. The second substrate 604 may be, for instance, a memory module, a computer motherboard, or another integrated circuit die. Generally, the purpose of an interposer 600 is to spread a connection to a wider pitch or to reroute a connection to a different connection. For example, an interposer 600 may couple an integrated circuit die to a ball grid array (BGA) 606 that can subsequently be coupled to the second substrate 604. In some embodiments, the first and second substrates 602/604 are attached to opposing sides of the interposer 600. In other embodiments, the first and second substrates 602/604 are attached to the same side of the interposer 600. And in further embodiments, three or more substrates are interconnected by way of the interposer 600.

The interposer 600 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer 600 may include metal interconnects 608 and vias 610, including but not limited to through-silicon vias (TSVs) 612. The interposer 600 may further include embedded devices 614, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 600. In accordance with embodiments of the invention, apparatuses or processes disclosed herein may be used in the fabrication of interposer 600.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is an apparatus comprising: a first transistor structure that includes: a first epitaxial structure, a second epitaxial structure, and a first set of one or more ribbons, wherein the first set of one or more ribbons extend from the first epitaxial structure to the second epitaxial structure; and wherein a first thickness between a first side and a second side of a middle region between a first end and a second end of one of the first set of one or more ribbons is greater than a second thickness between the first side and the second side of the one of the first set of one or more ribbons at the first end or the second end of the one of the first set of one or more ribbons; a second transistor structure that includes: a third epitaxial structure, a fourth epitaxial structure, and a second set of one or more ribbons, wherein the second set of one or more ribbons extend from the third epitaxial structure to the fourth epitaxial structure; and wherein the first transistor structure is on the second transistor structure; and wherein the first transistor structure is a PMOS transistor structure and the second transistor structure is an NMOS transistor structure.

Example 2 includes the apparatus of example 1, wherein the first set of one or more ribbons is directly physically coupled with the first epitaxial structure and with the second epitaxial structure.

Example 3 includes the apparatus of examples 1 or 2, wherein the first set of one or more ribbons include a first material, and further comprising a second material, wherein the second material separates the first set of one or more ribbons from the first epitaxial structure, and wherein the second material separates the first set of the one or more ribbons from the second epitaxial structure.

Example 4 includes the apparatus of examples 1, 2, or 3, wherein the first set of one or more ribbons is directly above the second set of one or more ribbons, wherein the first epitaxial structure is directly above the third epitaxial structure, and wherein the second epitaxial structure is directly above the fourth epitaxial structure.

Example 5 includes the apparatus of examples 1, 2, 3, or 4, wherein a crystalline structure of the first set of one or more ribbons is different than a crystalline structure of the second set of one or more ribbons.

Example 6 includes the apparatus of examples 1, 2, 3, 4, or 5, wherein the first set of one or more ribbons is formed from a first material, wherein the second set of one or more ribbons is formed from a second material.

Example 7 includes the apparatus of example 6, wherein the first material is silicon.

Example 8 includes the apparatus of example 7, wherein the second material is silicon.

Example 9 includes the apparatus of examples 1, 2, 3, 4, 5, 6, 7, or 8, further comprising: a first gate metal at least partially surrounding the first set of one or more ribbons; a second gate metal at least partially surrounding the second set of one or more ribbons; and wherein a material composition of the first gate metal and a material composition of the second gate metal are different material compositions.

Example 10 includes the apparatus of example 9, further comprising a liner between the first gate metal and the second gate metal to electrically isolate the first gate metal and the second gate metal.

Example 11 is a system comprising: a device; and an apparatus electrically coupled with the electrical device, the apparatus comprising: a first transistor structure that includes: a first epitaxial structure, a second epitaxial structure, and a first set of one or more ribbons, wherein the first set of one or more ribbons extend from the first epitaxial structure to the second epitaxial structure; and wherein one of the first set of one or more ribbons includes a seam between a first and of the first set of one or more ribbons and a second end of the first set of one or more ribbons; a second transistor structure that includes: a third epitaxial structure, a fourth epitaxial structure, and a second set of one or more ribbons, wherein the second set of one or more ribbons extend from the third epitaxial structure to the fourth epitaxial structure; and wherein the first transistor structure is on the second transistor structure; and wherein the first transistor structure is a PMOS transistor structure and the second transistor structure is an NMOS transistor structure, or wherein the first transistor structure is an NMOS transistor structure and the second transistor structure is a PMOS transistor structure.

Example 12 includes the system of example 11, wherein the seam separates a first portion of the one of the first set of one or more ribbons from a second portion of the one of the first set of one or more ribbons, wherein a crystalline structure of the first portion is discontinuous with a crystalline structure of the second portion at the seam.

Example 13 includes the system of examples 11 or 12, wherein the one of the first set of one or more ribbons includes only silicon.

Example 14 includes the system of examples 11, 12, or 13, wherein the first set of one or more ribbons include a first material, and further comprising a second material, wherein the second material separates the first set of one or more ribbons from the first epitaxial structure, and wherein the second material separates the first set of the one or more ribbons from the second epitaxial structure.

Example 15 includes the system of example 14, wherein the first set of one or more ribbons is directly above the second set of one or more ribbons, wherein the first epitaxial structure is directly above the third epitaxial structure, and wherein the second epitaxial structure is directly above the fourth epitaxial structure.

Example 16 includes the system of examples 11, 12, 13, 14, or 15, wherein the first set of one or more ribbons is directly physically coupled with the first epitaxial structure and with the second epitaxial structure, and wherein second set of one or more ribbons is directly physically coupled with the third epitaxial structure and with the fourth epitaxial structure.

Example 17 includes the system of examples 11, 12, 13, 14, 15, or 16, wherein the first set of one or more ribbons include a first material, and further comprising a second material, wherein the second material separates the first set of one or more ribbons from the first epitaxial structure, and wherein the second material separates the first set of the one or more ribbons from the second epitaxial structure, and wherein the first material and the second material are different materials.

Example 18 is a method comprising: forming a first transistor structure wherein the first transistor structure includes a first epitaxial structure, a second epitaxial structure, and a first set of one or more ribbons, wherein the first set of one or more ribbons extend from the first epitaxial structure to the second epitaxial structure, and wherein the first set of one or more ribbons includes a first material; forming a second transistor structure on the first transistor structure, wherein the second transistor structure includes a third epitaxial structure, a fourth epitaxial structure, and a second set of one or more ribbons, wherein the second set of one or more ribbons extend from the third epitaxial structure to the fourth epitaxial structure, wherein the second set of one or more ribbons is directly above the first set of one or more ribbons, and wherein the second set of one or more ribbons includes the first material; removing the second set of one or more ribbons to expose a first set of surfaces on the third epitaxial structure and a second set of surfaces on the fourth epitaxial structure; and growing a third set of one or more ribbons between the exposed first set of surfaces and the second set of surfaces, wherein the third set of one or more ribbons includes a second material that is different than the first material.

Example 19 includes the method of example 18, further comprising performing an oxidation process on the third set of one or more ribbons.

Example 20 includes the method of examples 18 or 19, further comprising depositing a gate metal around the third set of one or more ribbons.

What is claimed is:

1. An apparatus comprising:
a first transistor structure that includes:
a first epitaxial structure, a second epitaxial structure, and a first set of one or more ribbons, wherein the first set of one or more ribbons extend from the first epitaxial structure to the second epitaxial structure; and
wherein a first thickness between a first side and a second side of a middle region between a first end and a second end of one of the first set of one or more ribbons is greater than a second thickness between the first side and the second side of the one of the first set of one or more ribbons at the first end or the second end of the one of the first set of one or more ribbons;
a second transistor structure that includes:
a third epitaxial structure, a fourth epitaxial structure, and a second set of one or more ribbons, wherein the second set of one or more ribbons extend from the third epitaxial structure to the fourth epitaxial structure; and
wherein the first transistor structure is on the second transistor structure; and
wherein the first transistor structure is a PMOS transistor structure and the second transistor structure is an NMOS transistor structure.

2. The apparatus of claim 1, wherein the first set of one or more ribbons is directly physically coupled with the first epitaxial structure and with the second epitaxial structure.

3. The apparatus of claim 1, wherein the first set of one or more ribbons include a first material, and further comprising a second material, wherein the second material separates the first set of one or more ribbons from the first epitaxial structure, and wherein the second material separates the first set of the one or more ribbons from the second epitaxial structure.

4. The apparatus of claim 1, wherein the first set of one or more ribbons is directly above the second set of one or more ribbons, wherein the first epitaxial structure is directly above the third epitaxial structure, and wherein the second epitaxial structure is directly above the fourth epitaxial structure.

5. The apparatus of claim 1, wherein a crystalline structure of the first set of one or more ribbons is different than a crystalline structure of the second set of one or more ribbons.

6. The apparatus of claim 1, wherein the first set of one or more ribbons is formed from a first material, wherein the second set of one or more ribbons is formed from a second material.

7. The apparatus of claim 6, wherein the first material is silicon.

8. The apparatus of claim 7, wherein the second material is silicon.

9. The apparatus of claim 1, further comprising:
a first gate metal at least partially surrounding the first set of one or more ribbons;
a second gate metal at least partially surrounding the second set of one or more ribbons; and
wherein a material composition of the first gate metal and a material composition of the second gate metal are different material compositions.

10. The apparatus of claim 9, further comprising a liner between the first gate metal and the second gate metal to electrically isolate the first gate metal and the second gate metal.

11. A system comprising:
a device; and
an apparatus electrically coupled with the electrical device, the apparatus comprising:
a first transistor structure that includes:
a first epitaxial structure, a second epitaxial structure, and a first set of one or more ribbons, wherein the first set of one or more ribbons extend from the first epitaxial structure to the second epitaxial structure; and
wherein one of the first set of one or more ribbons includes a seam between a first and of the first set of one or more ribbons and a second end of the first set of one or more ribbons;
a second transistor structure that includes:
a third epitaxial structure, a fourth epitaxial structure, and a second set of one or more ribbons, wherein the second set of one or more ribbons extend from the third epitaxial structure to the fourth epitaxial structure; and
wherein the first transistor structure is on the second transistor structure; and
wherein the first transistor structure is a PMOS transistor structure and the second transistor structure is an NMOS transistor structure, or wherein the first transistor structure is an NMOS transistor structure and the second transistor structure is a PMOS transistor structure.

12. The system of claim 11, wherein the seam separates a first portion of the one of the first set of one or more ribbons from a second portion of the one of the first set of one or more ribbons, wherein a crystalline structure of the first portion is discontinuous with a crystalline structure of the second portion at the seam.

13. The system of claim 11, wherein the one of the first set of one or more ribbons includes only silicon.

14. The system of claim 11, wherein the first set of one or more ribbons include a first material, and further comprising a second material, wherein the second material separates the first set of one or more ribbons from the first epitaxial structure, and wherein the second material separates the first set of the one or more ribbons from the second epitaxial structure.

15. The system of claim 14, wherein the first set of one or more ribbons is directly above the second set of one or more ribbons, wherein the first epitaxial structure is directly above the third epitaxial structure, and wherein the second epitaxial structure is directly above the fourth epitaxial structure.

16. The system of claim 11, wherein the first set of one or more ribbons is directly physically coupled with the first epitaxial structure and with the second epitaxial structure, and wherein second set of one or more ribbons is directly physically coupled with the third epitaxial structure and with the fourth epitaxial structure.

17. The system of claim 11, wherein the first set of one or more ribbons include a first material, and further comprising a second material, wherein the second material separates the first set of one or more ribbons from the first epitaxial structure, and wherein the second material separates the first set of the one or more ribbons from the second epitaxial structure, and wherein the first material and the second material are different materials.

18. A method comprising:
forming a first transistor structure wherein the first transistor structure includes a first epitaxial structure, a second epitaxial structure, and a first set of one or more ribbons, wherein the first set of one or more ribbons extend from the first epitaxial structure to the second epitaxial structure, and wherein the first set of one or more ribbons includes a first material;
forming a second transistor structure on the first transistor structure, wherein the second transistor structure includes a third epitaxial structure, a fourth epitaxial structure, and a second set of one or more ribbons, wherein the second set of one or more ribbons extend from the third epitaxial structure to the fourth epitaxial structure, wherein the second set of one or more ribbons is directly above the first set of one or more ribbons, and wherein the second set of one or more ribbons includes the first material;
removing the second set of one or more ribbons to expose a first set of surfaces on the third epitaxial structure and a second set of surfaces on the fourth epitaxial structure; and
growing a third set of one or more ribbons between the exposed first set of surfaces and the second set of surfaces, wherein the third set of one or more ribbons includes a second material that is different than the first material.

19. The method of claim 18, further comprising performing an oxidation process on the third set of one or more ribbons.

20. The method of claim 18, further comprising depositing a gate metal around the third set of one or more ribbons.
